(19) United States
(12) Patent Application Publication
(10) Pub. No.: US 2007/0081679 A1
(43) Pub. Date: Apr. 12, 2007

(54) Portable audio drive unit

(75) Inventors: Nobukazu Suzuki, Kanagawa (JP); Masaru Uryu, Chiba (JP); Yoshio Ohashi, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: SONY CORPORATION, Shinagawa-ku (JP)

(21) Appl. No.: 11/528,466

(22) Filed: Sep. 28, 2006

(30) Foreign Application Priority Data
Oct. 7, 2005 (JP) 2005-295636

(51) Int. Cl. H01L 41/00; H04R 25/00

(52) U.S. Cl. 381/152; 310/26

(57) ABSTRACT

A portable audio drive unit has a case, an audio signal output section that outputs an audio signal, and a magnetostrictive actuator that drives on the basis of the audio signal output from the audio output section. The magnetostrictive actuator includes a displacement transfer section. The displacement transfer section has a driving rod. The displacement transfer section transfers a displacement of the driving rod. The magnetostrictive actuator is arranged in the case with the displacement transfer section being protruded from the case or being retractable into the case.

### CROSSREFERENCE TO RELATED APPLICATION

The present invention contains subject matter related to Japanese Patent Application JP 2005-295636 filed in the Japanese Patent Office on Oct. 7, 2005, the entire contents of which being incorporated herein by reference.

### BACKGROUND OF THE INVENTION

1. Field of the Invention

The present invention relates to a portable audio drive unit equipped with a magnetostrictive actuator driving based on an audio signal.

2. Description of Related Art

Japanese Patent Application Publication H04-313999 has disclosed an audio output device for obtaining an audio output by driving a diaphragm with a magnetostrictive actuator. The magnetostrictive actuator refers to an actuator that uses a magnetostrictive element whose shape changes when an external magnetic field is supplied.

FIG. 1 shows a configuration of this type of an audio output device 300. This audio output device 300 has a player 301, an amplifier 302, a magnetostrictive actuator 303, and a diaphragm 304.

The player 301 reproduces, for example, a compact disc (CD), a mini-disc (MD), a digital versatile disc (DVD) to output an audio signal. The amplifier 302 amplifies the audio signal received from this player 301 and supplies it to the magnetostrictive actuator 303. The magnetostrictive actuator 303 has a driving rod 303a for transferring a displacement output thereof. An end of this driving rod 303a abuts against the diaphragm 304.

The magnetostrictive actuator 303 drives the diaphragm 304 in accordance with the audio signal. That is, the driving rod 303a of the magnetostrictive actuator 303 is displaced corresponding to a waveform of the audio signal, a displacement of which is in turn transferred to the diaphragm 304. Accordingly, the diaphragm 304 outputs audio that corresponds to the audio signal.

### SUMMARY OF THE INVENTION

Since the magnetostrictive actuator gives large stress when any deformation in the magnetostrictive element occurs, a relatively large sound volume can be produced from a certain type of the diaphragm even if the magnetostrictive actuator is small. The magnetostrictive actuator can output audio from even a relatively hard diaphragm (iron plate etc.). Further, this magnetostrictive actuator is excellent in response speed and its magnetostrictive element alone operates in the order of nanoseconds.

Consider here a speaker system having portability. A typical speaker necessitates a diameter corresponding to its sound volume. If portability is emphasized to make the speaker smaller and lighter, the speaker diameter is reduced smaller. In such the speaker, however, it may be impossible to secure a sufficient sound volume. That is, there is a trade-off between the portability and the sound volume.

It is desirable to provide a portable audio drive unit that can obtain a sufficient sound volume while securing portability.

According to an embodiment of the invention, there is provided a portable audio drive unit. The portable audio drive unit has a case, an audio signal output section that outputs an audio signal, and a magnetostrictive actuator that drives on the basis of the audio signal output from the audio output section. The magnetostrictive actuator includes a displacement transfer section. The displacement transfer section has a driving rod. The displacement transfer section transfers a displacement of the driving rod. The magnetostrictive actuator is arranged in the case with the displacement transfer section protruding from the case. The displacement transfer section may be retractable into the case.

According to the embodiment of the present invention, the portable audio drive unit is equipped with a magnetostrictive actuator. This magnetostrictive actuator drives on the basis of an audio signal received from the audio signal output section. For example, if the portable audio drive unit is a hard disk drive (HDD) player, the magnetostrictive actuator drives on the basis of an audio signal obtained by expanding compressed audio data read out of the HDD. Further, for example, if the portable audio drive unit is a portable telephone, the magnetostrictive actuator drives on the basis of an audio signal obtained by expanding compressed audio data at an audio-processing section.

This magnetostrictive actuator is arranged in the case with the displacement transfer section for transferring a displacement of the driving rod protruding from the case. Alternatively, this magnetostrictive actuator may be arranged in the case with the displacement transfer section being retractable into the case. In this portable audio drive unit, by permitting the displacement transfer section protruding from the case to abut against a predetermined diaphragm, it is possible to vibrate this diaphragm, thereby obtaining an audio output.

In this embodiment, the magnetostrictive actuator may be contained, for example, in a small container whose one surface is constituted of a diaphragm with the driving rod abutting against the one surface, attached to a displacement expander that expands a displacement of the driving rod, or not contained in the small container nor attached to the displacement expander, that is, exposed.

When the magnetostrictive actuator is contained in the small container, the displacement transfer section comes in the one surface constituting the diaphragm. Further, when the magnetostrictive actuator is attached to the displacement expander, the displacement transfer section comes in the displacement expander. Further, when the magnetostrictive actuator is exposed, the displacement transfer section comes in the driving rod.

According to the portable audio drive unit as the embodiment of the present invention, it is possible to obtain a sufficient sound volume if a predetermined diaphragm against which the displacement transfer section abuts is large and to avoid a large diaphragm to obtain a sufficient sound volume being equipped with securing portability. It is to be noted that if the driving rod is retractable into the case, by protruding this driving rod from the case only when obtaining an audio output by permitting the driving rod to abut against the predetermined diaphragm, it is possible to avoid occurrence of a hindrance of the protruded driving rod otherwise.

For example, the case has a sucker to stick the case to a predetermined diaphragm with the displacement transfer section abutting against this predetermined diaphragm. By sticking the case to the predetermined diaphragm by using this sucker, the displacement transfer section can be kept its abutting condition against the predetermined diaphragm. This enables the user to avoid holding the case in order to keep the displacement transfer section in this abutting condition, thereby improving usability.

For example, an equalizer section that corrects a frequency response of an audio signal may be inserted between the audio signal output section and the magnetostrictive actuator. This permits a user to select a content to be corrected by the equalizer among a plurality of correction contents. A frequency response of an audio output from the predetermined diaphragm is influenced by a material (e.g., wood, glass, metal, or plastic) of the predetermined diaphragm against which the displacement transfer section abuts, a thickness of the diaphragm, etc. Therefore, by selecting a correction content to be corrected by the equalizer section among correction contents that correspond to a plurality of possible materials and thicknesses of the predetermined diaphragm, the frequency response can be corrected corresponding to actual material and thickness of the predetermined diaphragm, thereby permitting the frequency response of the audio output to get closer to a predetermined frequency response irrespective of the materials and thicknesses of the predetermined diaphragm.

According to another embodiment of the invention, the portable audio drive unit may have a switchover mechanism that switches a condition of arranging the magnetostrictive actuator between a first condition in which the driving rod protrudes from the case and a second condition in which the driving rod abuts against the diaphragm. In this embodiment, in the second condition where no driving rod protrudes from the case, this driving rod abuts against the diaphragm. This allows an audio output to be obtained by vibrating this diaphragm.

According to further embodiment of the invention, the magnetostrictive actuator may be detachably arranged in the case. If so, the portable audio drive unit may have a wireless transmission section that transmits an audio signal output from the audio signal output section when the magnetostrictive actuator is detached from the case and a wireless reception section that receives the audio signal from the wireless transmission section when the magnetostrictive actuator is detached from the case. The wireless reception section is integrally fixed at the magnetostrictive actuator.

When the magnetostrictive actuator is detached from the case, the audio signal output from the audio signal output section is transmitted by the wireless transmission section to the wireless reception section on the side of the magnetostrictive actuator. The magnetostrictive actuator drives based on the audio signal received by this wireless reception section. Therefore, by permitting the displacement transfer section of the magnetostrictive actuator detached from this case to abut against the predetermined diaphragm, this diaphragm can vibrate to obtain an audio output.

This may be attained only by permitting the magnetostrictive actuator detached from the case to abut against the predetermined diaphragm, thereby facilitating handling. In this situation, the magnetostrictive actuator may be stuck to the predetermined diaphragm by, for example, a sucker, thereby improving usability of the user.

The concluding portion of this specification particularly points out and directly claims the subject matter of the present invention. However those skilled in the art will best understand both the organization and method of operation of the invention, together with further advantages and objects thereof, by reading the remaining portions of the specification in view of the accompanying drawing(s) wherein like reference characters refer to like elements.

### BRIEF DESCRIPTION OF THE DRAWINGS

FIG. 1 is a block diagram for showing a configuration of an audio output device that employs a magnetostrictive actuator;

FIG. 2 is a block diagram for showing a circuit configuration of an HDD player as a portable audio drive unit according to a first embodiment of the invention;

FIG. 3A is a drawing for showing a configuration of a magnetostrictive actuator and FIG. 3B is an illustration for illustrating magnetic flux lines in the magnetostrictive actuator;

FIG. 4 is a schematic perspective view of the HDD player as seen from a front side thereof;

FIG. 5 is a schematic perspective view (where a driving rod protrudes) of the HDD player as seen from a rear side thereof;

FIG. 6 is a schematic perspective view (where the driving rod is retracted) of the HDD player as seen from the rear side thereof;

FIG. 7 is a rear view (where the driving rod protrudes) of the HDD player as seen from the rear side thereof;

FIG. 8 is a diagram for showing a condition where the protruded driving rod abuts against a diaphragm;

FIG. 9 is an explanatory illustration of selection of correction characteristics by an equalizer;

FIG. 10 is an explanatory illustration that illustrates a display example of melodies matching “wood”, which are stored in an HDD;

FIG. 11 is a rear view (where the driving rod is retracted) of the HDD player as seen from the rear side thereof;

FIG. 12 is a drawing for showing a condition where the driving rod is retracted;

FIG. 13 is an explanatory illustration that illustrates a choice between an actuator output condition and a headphone output condition;

FIG. 14 is a rear view of the HDD player having two magnetostrictive actuators arranged in a case in which the driving rods protrude from the case;

FIG. 15 is a schematic cross-sectional view of the HDD player having the two magnetostrictive actuators arranged in the case in which the driving rods protrude from the case;

FIG. 16 is a block diagram for showing a circuit configuration of an HDD player as a portable audio drive unit according to a second embodiment of the invention;

FIG. 17 is a block diagram for showing a circuit configuration of a body section of an HDD player as a portable audio drive unit according to a third embodiment of the invention;

FIG. 18 is a block diagram for showing a circuit configuration of a magnetostrictive actuator section used in the HDD player as a portable audio drive unit according to the third embodiment of the invention;

FIG. 19 is an explanatory illustration of choice in use condition between wireless use and wired use;

FIG. 20 is an explanatory illustration of how the magnetostrictive actuator is contained in the case or separated from the case;

FIG. 21 is an explanatory illustration for illustrating conditions where the driving rod protrudes and is retracted;

FIG. 22 is a drawing for showing a condition where the magnetostrictive actuator section is placed on a wall made of a magnetic substance;

FIG. 23 is a drawing for showing a condition where the magnetostrictive actuator section having suckers is placed on a wall made of a nonmagnetic substance;

FIG. 24 is a drawing for showing a condition where the magnetostrictive actuator section having the suckers is placed on an upper plate (which is made of a nonmagnetic substance) of a desk;

FIG. 25A is a side view of the magnetostrictive actuator section having the suckers and FIG. 25B is a front view thereof, each of which shows a configuration of the magnetostrictive actuator section having the suckers;

FIG. 26 is a drawing for showing a configuration of an audio output device;

FIG. 27 is a drawing for showing a use example of the audio output devices;

FIG. 28 is a drawing for showing another use example of the audio output section;

FIG. 29A is a front view of a displacement expander on which the magnetostrictive actuator is mounted and FIG. 29B is a side view thereof;

FIG. 30A is an explanatory illustration for illustrating a condition where the magnetostrictive actuator is mounted on the head of a human being and FIG. 30B is a drawing for illustrating a device on which the magnetostrictive actuator is mounted;

FIG. 31 is a block diagram for showing a configuration of a portable telephone as a portable audio drive unit according to a fourth embodiment of the invention;

FIG. 32A is a front view of the portable telephone on which the magnetostrictive actuator is mounted and FIG. 32B is a side view thereof, each of which shows a condition where the magnetostrictive actuator is mounted on a case of the portable telephone; and

FIG. 33 is an illustration for illustrating a use condition of bone phone by use of bone conduction.

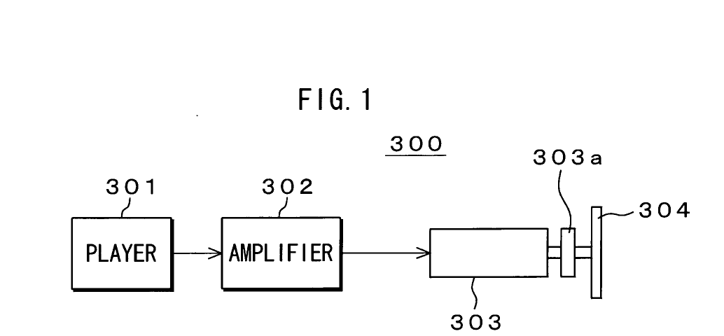

### DESCRIPTION OF THE PREFERRED EMBODIMENTS

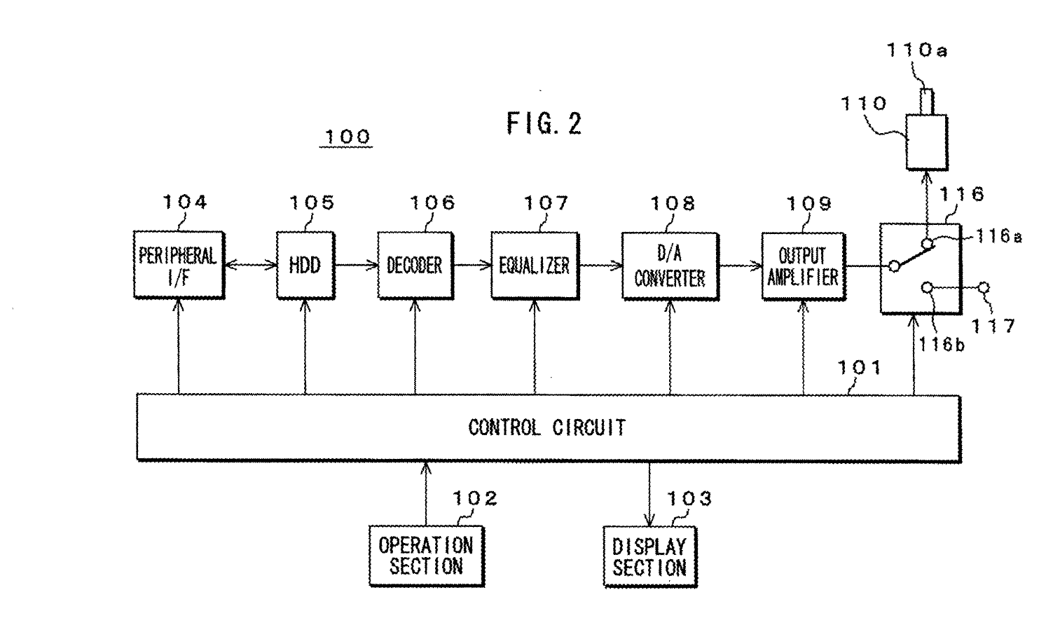

The following will describe a first embodiment of the present invention. FIG. 2 shows a circuit configuration of an HDD player 100 as a portable audio drive unit according to the first embodiment of the invention.

This HDD player 100 has a control circuit 101 for controlling operations of an entirety of the player. To this control circuit 101, an operation section 102 and a display section 103 as a user interface are connected. The display section 103 is constituted of, for example, a liquid crystal display (LCD).

This HDD player 100 further has an peripheral interface (I/F) 104, an HDD 105, a decoder 106, an equalizer 107, a D/A converter 108, an output amplifier 109, a magnetostrictive actuator 110, a changeover switch 116, and a headphone jack 117.

The peripheral interface 104 is an interface such as a universal serial bus (USB) or an IEEE1394 interface for transferring compressed audio data with a personal computer (PC), not shown.

The HDD 105 receives the compressed audio data from a personal computer via the peripheral interface 104 and stores it. The decoder 106 expands the compressed audio data read out of the HDD 105. The equalizer 107 performs correction processing of a frequency response on the audio data output from the decoder 106.

As described later, the user can switch by his or her manipulation between an actuator output condition for supplying the magnetostrictive actuator 110 with an audio signal from the output amplifier 109 as a drive signal and a headphone output condition for outputting the audio signal from the output amplifier 109 to the headphone jack 117. Further, in the actuator output condition, the user may operate to select a protrusion condition (first condition) in which a driving rod 110a protrudes from a case 120 or a retraction condition (second condition) in which the driving rod 110a is retracted in a recess portion 122.

If the first condition is selected in the actuator output condition, an audio output is obtained from a predetermined diaphragm that the driving rod 110a of the magnetostrictive actuator 110 abuts against. A frequency response of this audio output signal is influenced by a material (e.g., wood, glass, metal, or plastic) of the predetermined diaphragm, a thickness of the diaphragm, etc. Therefore, in such condition, the user can select what is to be corrected by the equalizer 107 from among correction contents that correspond to a plurality of materials and thicknesses.

Further, if the second condition is selected in the actuator output condition, the driving rod 110 is permitted to abut against the diaphragm mounted on a top of the case. This enables a correction content by the equalizer 107 to be automatically set to a correction content that corresponds to that diaphragm. In the headphone output condition, a correction content by the equalizer 107 is automatically set under a control of the control circuit 101 to correction content that corresponds to the headphone.

The D/A converter 108 converts a digital signal of audio data whose frequency response has been corrected by the equalizer 107 into an analog signal. The output amplifier 109 amplifies the audio signal output from the D/A converter 108.

The change-over switch 116 switches between a supply of the audio signal from the output amplifier 109 to the magnetostrictive actuator 110 as a drive signal and output of it to the headphone jack 117 under a control of the control circuit 101. A movable terminal of this change-over switch 116 is connected to an output side of the output amplifier 109, and a fixed terminal 116a thereof is connected to the magnetostrictive actuator 110 and a fixed terminal 116b thereof is connected to the headphone jack 117.

If the user selects the actuator output condition, the change-over switch 116 is connected to the fixed terminal 116a. The audio signal from the output amplifier 109 is then supplied as a drive signal to the magnetostrictive actuator 110 via the fixed terminal 116a of the change-over switch 116. On the other hand, if the user selects the headphone output condition, the change-over switch 116 is connected to the fixed terminal 116b. The audio signal from the output amplifier 109 is then output to the headphone jack 117 via the fixed terminal 116b of the change-over switch 116.

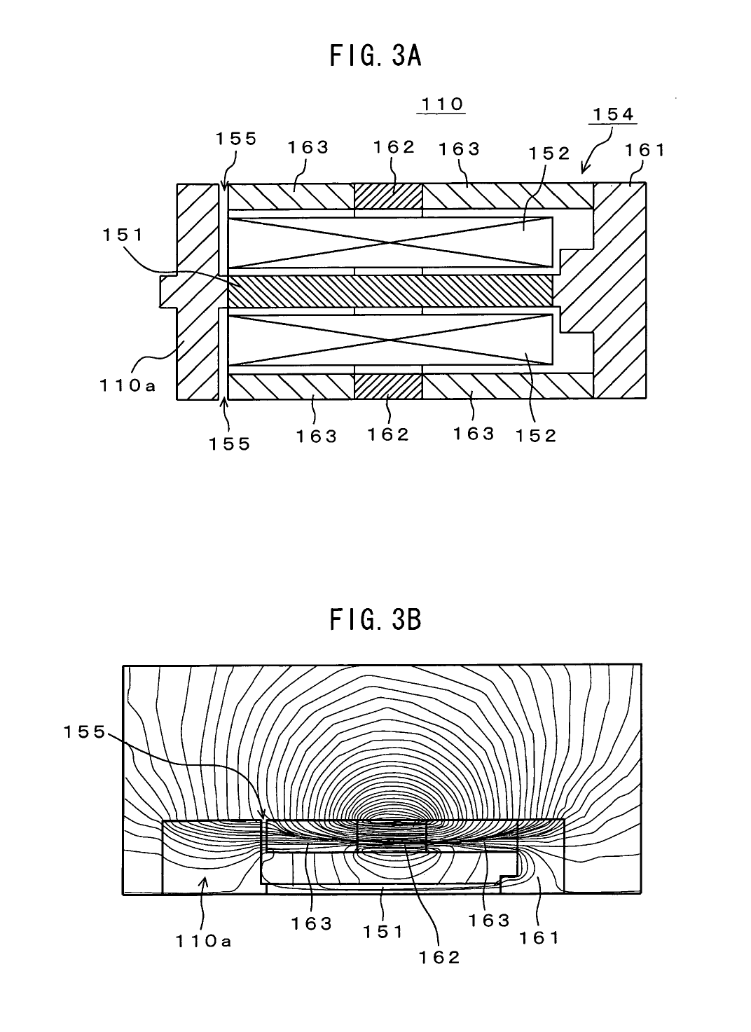

FIG. 3A shows a configuration of the magnetostrictive actuator 110. The magnetostrictive actuator 110 has a rod-shaped magnetostrictive element 151 that is displaced in an elongation direction, a solenoid coil 152 serving as a magnetic field generation section and arranged around this magnetostrictive element 151 for applying a control magnetic field on this magnetostrictive element 151, a driving rod 110a as movable member which is coupled to one end of the magnetostrictive element 151 in order to transfer a displacement output of the magnetostrictive actuator 110, and a containing section 154 for containing the magnetostrictive element 151 and the solenoid coil 152.

The containing section 154 is constituted of a fixed plate 161, a permanent magnet 162, and cylindrical cases 163. To the fixed plate 161, the other end of the magnetostrictive element 151 is coupled so that the magnetostrictive element 151 may be supported by this fixed plate 161. The permanent magnet 162 for applying a static bias magnetic field on the magnetostrictive element 151 and the cylindrical cases 163 constituting a magnetic circuit are arranged around the magnetostrictive element 151 which is contained. The cylindrical cases 163 are mounted on a side of the driving rod 110a of the permanent magnet 162 and on a side of the fixed plate 161 and can,be made of a ferromagnetic substance so that it may efficiently apply a static bias magnetic field on the magnetostrictive element 151. Further, the fixed plate 161 can also be made of a ferromagnetic substance so as to further efficiently apply a static bias magnetic field on the magnetostrictive element 151.

A gap 155 is secured between the driving rod 110a and the containing section 154 and the driving rod 110a is made of a ferromagnetic substance so that it may be attracted to the permanent magnet 162. Accordingly, a magnetic attraction occurs between the driving rod 110a and the containing section 154, thereby applying a preload on the magnetostrictive element 151 mounted on the driving rod 110a.

FIG. 3B shows magnetic flux lines over the magnetostrictive actuator 110 shown in FIG. 3A. The magnetic flux lines that originate at the permanent magnet 162 pass through the cylindrical case 163, the gap 155, the driving rod 110a, the fixed plate 161 and the other cylindrical case 163 in this order and come back to the permanent magnet 162. Accordingly, a magnetic attraction occurs between the driving rod 110a and the containing section 154, thereby enabling a preload to be applied on the magnetostrictive element 151. Further, some of the magnetic flux lines pass through the cylindrical case 163, the gap 155, the driving rod 110a, the magnetostrictive element 151, the fixed plate 161 and the other cylindrical case 163 in this order and come back to the permanent magnet 162. It is thus possible to apply a static bias magnetic field on the magnetostrictive element 151.

Since the driving rod 110a is not supported by roller bearings in this magnetostrictive actuator 110, there is no problem of a friction between the driving rod 110a and the roller bearing, thereby enabling losses in displacement output to be greatly reduced.

Further, since the preload is applied on the magnetostrictive element 151 by a magnetic attraction in this magnetostrictive actuator 110, even if a period of displacement of the magnetostrictive element 151 is short, it is possible to continuously apply the preload thereon. This allows to be correctly obtained a displacement output that corresponds to a control current supplied to the solenoid coil 152.

Accordingly, in this magnetostrictive actuator 110, a relationship between a control current flowing through the solenoid coil 152 and a displacement of the driving rod 110a comes close to linearity, so that it is possible to mitigate a distortion that occurs due to characteristics of this magnetostrictive actuator 110, thereby reducing loads on correction of a feedback.

Further, in this magnetostrictive actuator 110, the permanent magnet 162 is placed between the two cylindrical cases 163, 163 so that a static bias magnetic field applied on the magnetostrictive element 151 can be made uniform more than a case where the permanent magnet is mounted at the fixed plate 161. Moreover, it is unnecessary to provide roller bearings to support the driving rod 110a, a coupling member to connect the driving rod 110a and the containing section 154 to each other, or a spring to apply a preload on the magnetostrictive element 151, thereby enabling the unit to be easily miniaturized and any costs for constructing it to be reduced.

The following will describe operations of the HDD player 100 as shown in FIG. 2.

The HDD 105 receives the compressed audio data the personal computer, not shown, via the peripheral I/F 104 and stores it.

In the reproduction thereof, the user operates the operation section 102 to select either the actuator output condition or the headphone output condition. If the actuator output condition is selected, the change-over switch 116 is connected to the fixed terminal 116a. On the other hand, if the headphone output condition is selected, the change-over switch 116 is connected to the fixed terminal 116b.

In this reproduction, compressed audio data is read out of the HDD 105 and supplied to the decoder 106. The decoder 106 expands the compressed audio data. Audio data output from this decoder 106 is supplied to the equalizer 107. The equalizer 107 performs any correction processing of frequency response on the audio data. If the first condition is selected in the actuator output condition, the user selects a predetermined correction content among correction contents that correspond to a plurality of thicknesses and materials. Further, if the second condition is selected in the actuator output condition, a correction content that corresponds to a diaphragm mounted on the top of the case is selected automatically. Furthermore, if the headphone output condition is selected, a correction content that corresponds to the headphone is selected automatically.

The D/A converter 108 converts a digital signal of the audio data whose frequency response has been corrected by the equalizer 107 into an analog signal. The output amplifier 109 then amplifies the analog audio signal output from the D/A converter 108. Further, if the actuator output condition is selected, the audio signal from the output amplifier 109 is supplied to the magnetostrictive actuator 110 via the fixed terminal 116a of the change-over switch 116 as a drive signal. On the other hand, if the headphone output condition is selected, the audio signal from the output amplifier 109 is output to the headphone jack 117 via the fixed terminal 116b of the change-over switch 116.

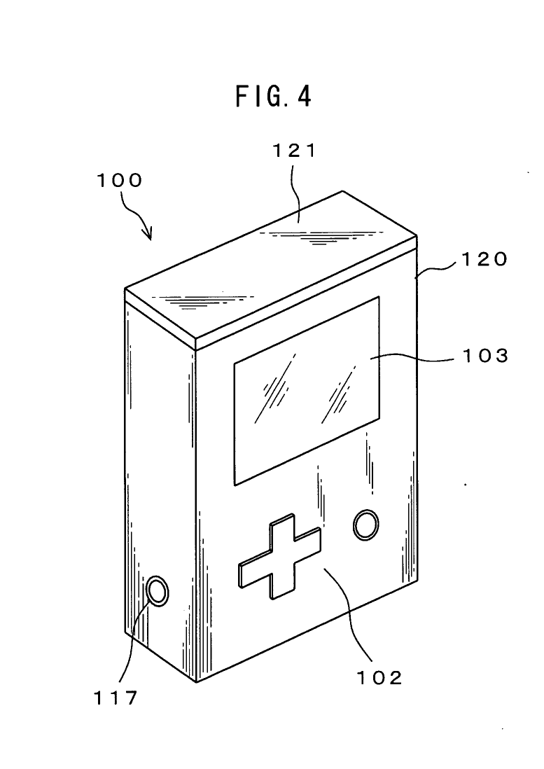

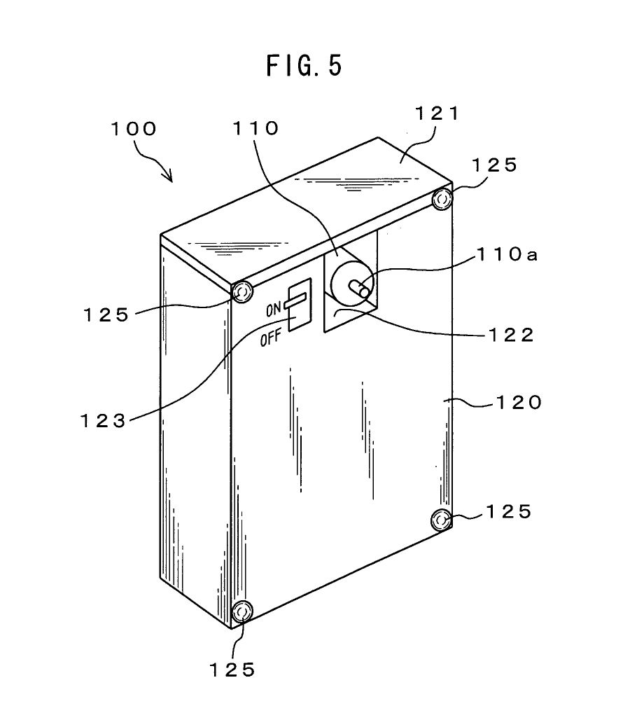

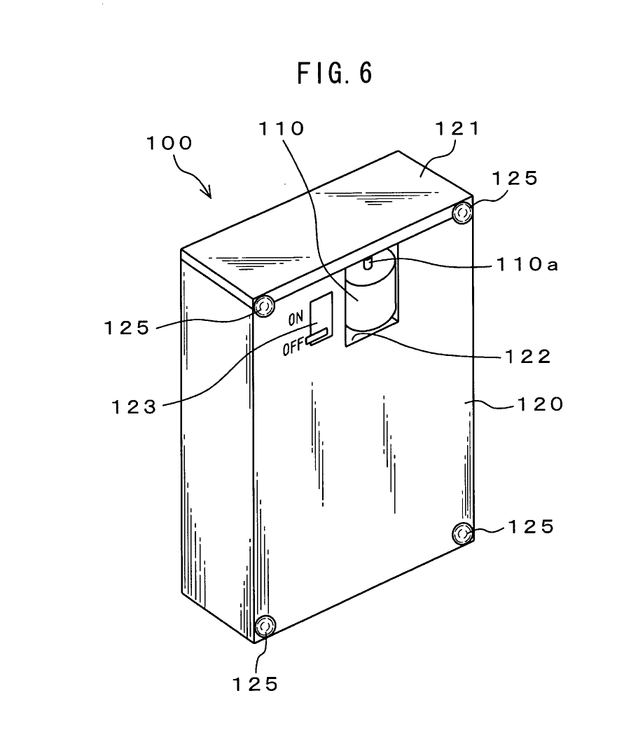

FIGS. 4-6 each show an external view of the HDD player 100. FIG. 4 is a schematic perspective view of the HDD player 100 as seen from a front side thereof. FIGS. 5 and 6 are each a schematic perspective view of the HDD player 100 as seen from a rear side thereof.

As shown in FIG. 4, on a front face of the case 120 of the HDD player 100, the operation section 102 and the display section 103 are arranged. Further, on a left side of this case 120, the headphone jack 117 is arranged. Further, on the top of the case 120, as shown in FIG. 4, a diaphragm 121 made of a predetermined material, for example, metal is mounted.

Further, in a back side of the case 120, as shown in FIGS. 5 and 6, at an upper part thereof, a recess portion 122 is formed for containing the magnetostrictive actuator 110 in such a manner that it is retractable. Further, at four corners of the back side of the case 120, which will be described later, suckers 125 are mounted to stick the case 120 to a predetermined diaphragm in a condition where the driving rod 110a protruding from this case 120 abuts against this predetermined diaphragm.

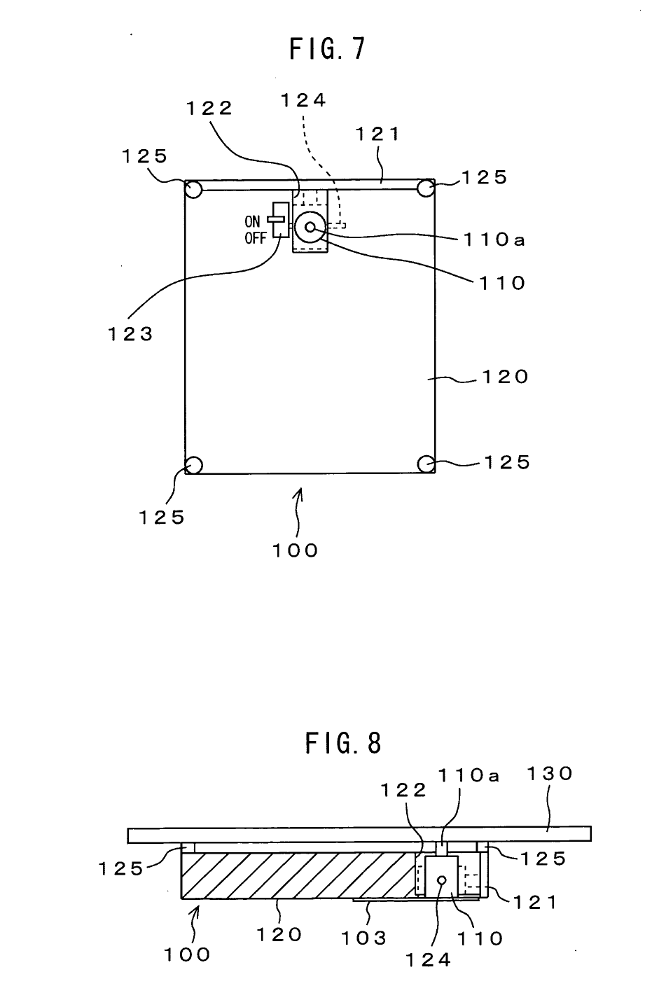

If a slide operation section 123 arranged on the back side of the case 120 is set to an “ON” side, as shown in FIG. 5, the magnetostrictive actuator 110 rotates around a rotation axis 124, not shown in FIG. 5, thereby permitting the driving rod 110a to protrude from the case 120 (the first condition). FIG. 7 shows this protrusion condition as viewed from the rear side thereof.

The driving rod 110a of the magnetostrictive actuator 110 that protrudes from the case 120 abuts against a predetermined diaphragm 130, as shown in FIG. 8. If, in this abutting condition, the magnetostrictive actuator 110 drives based on an audio signal amplified by the output amplifier 109 as described above, the diaphragm 130 vibrates corresponding to the audio signal, thereby giving audio output based on the audio signal by the diaphragm 130.

In such condition that the driving rod 110a of the magnetostrictive actuator 110 abuts against the predetermined diaphragm 130 so that the audio output may be produced by this diaphragm 130, the user can select a correction content that corresponds to the material of this diaphragm 130 as what is to be corrected in the above-described equalizer 107.

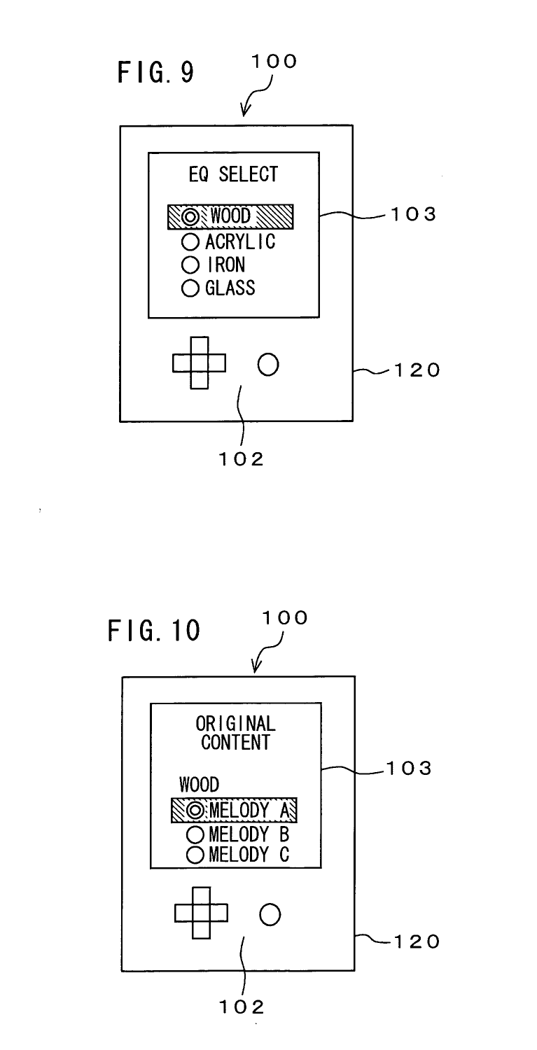

If the slide operation section 123 is set to the “ON” side, as shown in FIG. 9, options of the material and the thickness are displayed on the display section 103 arranged on the front side of the case 120 (although only the material options are indicated in a display example of FIG. 9, the thickness options are given after, for example, any one of the material options is selected). In this display condition, the user can operate the operation section 102 to select a material of the above-described predetermined diaphragm 130 or an almost equivalent material. Accordingly, a correction content of a frequency response in the equalizer 107 can be made to correspond to the material of the predetermined diaphragm 130, so that a frequency response of an audio output of this diaphragm 130 can get close to a predetermined frequency response irrespective of the material of this diaphragm 130.

It is to be noted that by downloading or presetting melodies that match diaphragms made of a variety of materials in the HDD 105 as original contents, it is possible to play back and enjoy a melody matching the material of the predetermined diaphragm 130. For example, FIG. 10 shows condition in which melodies stored in the HDD 105 that match “wood”, for example, melodies A, B, and C are displayed on the display section 103. The user operates the operation section 102 in this display condition to select a desired one of the melodies.

Further, in a condition where the driving rod 110a thus abuts against the predetermined diaphragm 130, it is possible to stick the case 120 to this diaphragm 130 by using the suckers 125 mounted on the back side of the case 120. It is thus possible to retain this abutting condition and improve usability even if the user does not hold the case 120 continuously.

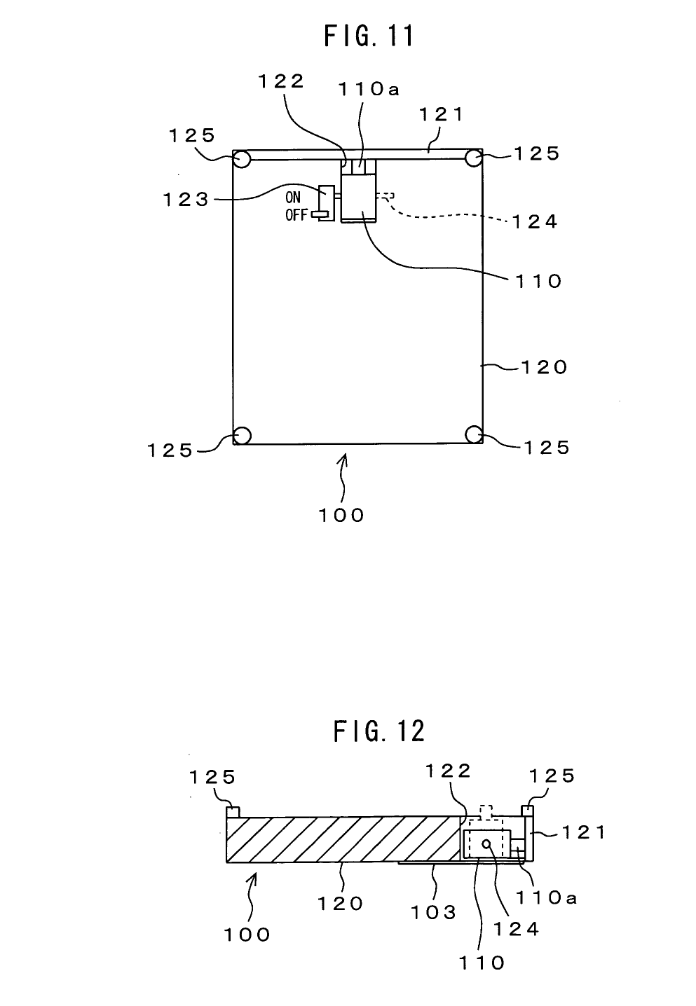

Further, if the slide operation section 123 provided on the back side of the case 120 is set to an “OFF” side, as shown in FIG. 6, the magnetostrictive actuator 110 rotates around the rotation axis 124, not shown in FIG. 6, thereby retracting the driving rod 110a into the recess portion 122 (the second condition). FIG. 11 shows this retraction condition as viewed from the rear side thereof.

In the retraction condition where the driving rod 110a is retracted into the recess portion 122, as shown in FIGS. 11 and 12, the driving rod 110a of the magnetostrictive actuator 110 abuts against the diaphragm 121. In this abutting condition, when the magnetostrictive actuator 110 drives based on an audio signal amplified by the output amplifier 109 as described above, the diaphragm 121 vibrates corresponding to the audio signal, thereby giving audio output based on the audio signal. It is to be noted that correction content of a frequency response to be corrected by the equalizer 107 is automatically set to correction content that corresponds to this diaphragm 121.

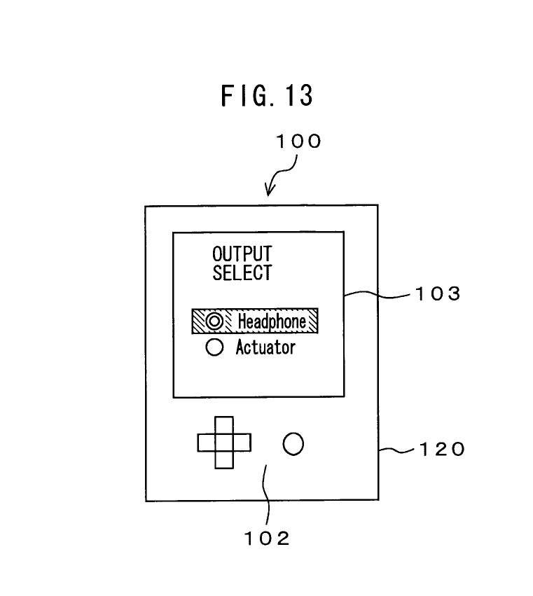

It is to be noted that when selecting either the actuator output condition or the headphone output condition, as shown in FIG. 13, the display section 103 arranged on the front side of the case 120 displays options of the actuator and the headphone. In this display condition, the user can operate the operation section 102 to select either the actuator output condition or the headphone output condition.

According to the above-described HDD player 100, by increasing a size of the predetermined diaphragm 130 which the driving rod 110a abuts against with this driving rod 110a protruding from the case 120, it is possible to obtain a sufficient sound volume and, further, to avoid being equipped with a large diaphragm in order to obtain a sufficient sound volume, thus enabling securing portability.

Further, in this HDD player 100, the driving rod 110a is permitted to protrude from the case 120 only when obtaining an audio output by causing this driving rod 110a to abut against the predetermined diaphragm 130. Otherwise, the driving rod 110a is retracted into the recess portion 122, thereby avoiding the protrusion of the driving rod 111a from becoming a hindrance.

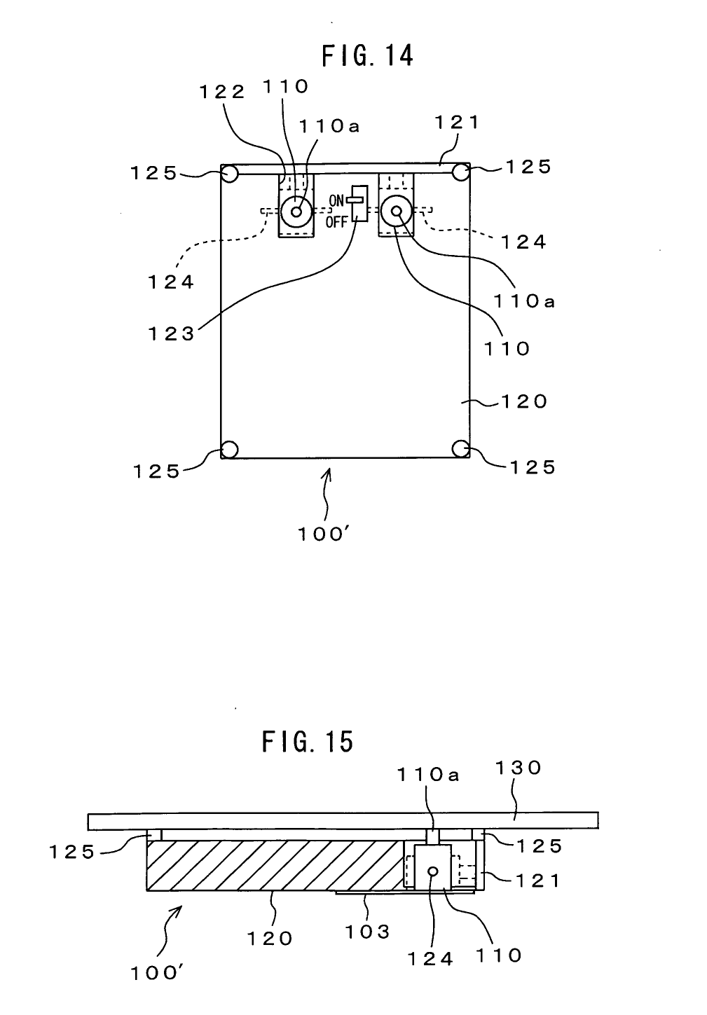

For ease of explanation, a monophonic type of the HDD player 100 has been described above in which only one magnetostrictive actuator 110 is arranged in the case 120. However, a stereo type of an HDD player 100′ can be configured similarly in which two magnetostrictive actuators 110, 110 are arranged in the case 120. FIGS. 14 and 15 show the HDD player 100′ in which the two magnetostrictive actuators 110 are arranged in the case 120 with the driving rods 110a, 110a protruding from the case 120.

Further, although the above-described HDD player 100 has been described as a type to switch between the actuator output condition and the headphone output condition, it can be also configured so that these two pieces of output condition would be employed at the same time.

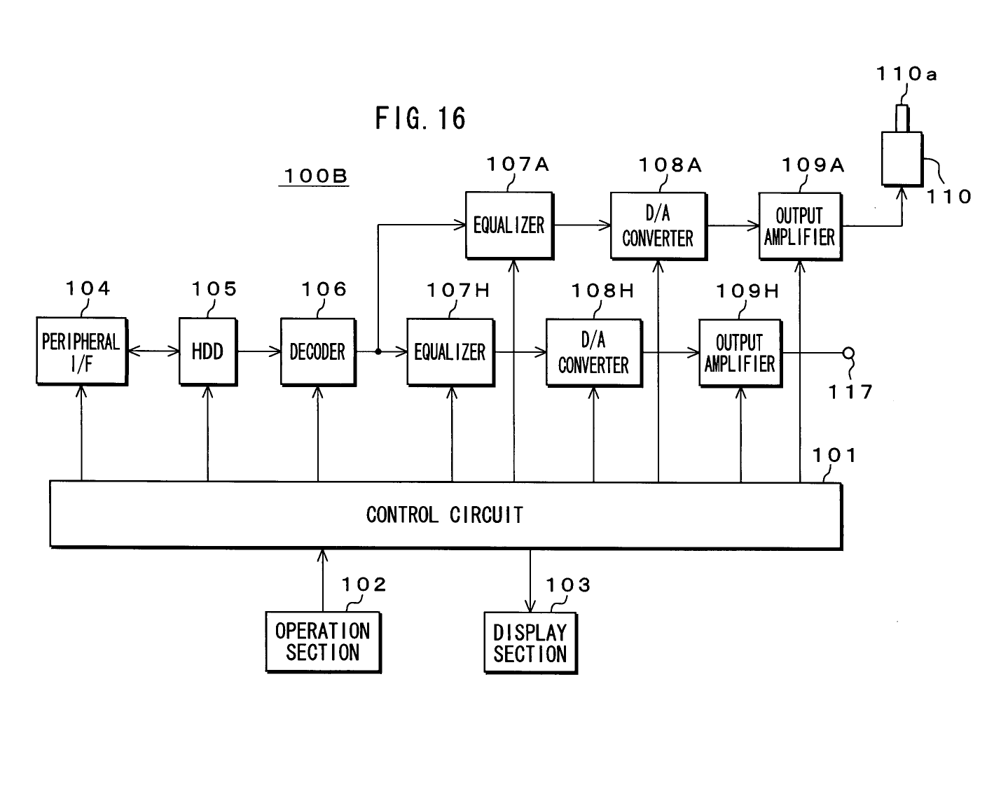

FIG. 16 shows a configuration of an HDD player 100B as a portable audio drive unit according to a second embodiment of the invention, in which the actuator output condition and the headphone output condition can be used at the same time. In this FIG. 16, components that correspond to those of FIG. 2 are indicated by the same symbols and their detailed explanation will be omitted.

This HDD player 100B has an equalizer 107A, a D/A converter 108A, and an output amplifier 109A, which are provided to obtain a drive signal for a magnetostrictive actuator 110. The equalizer 107A, the D/A converter 108A, and the output amplifier 109A correspond to the equalizer 107, the D/A converter 108, and the output amplifier 109 shown in FIG. 2, respectively.

In this embodiment, correction content of a frequency response to be corrected by the equalizer 107A is set to a predetermined correction content selected by the user among correction contents that correspond to a plurality of materials and thicknesses if protrusion condition in which a driving rod 110a protrudes from a case 120 (the first condition) is selected. On the other hand, if retraction condition in which the driving rod 110a is retracted into a recess portion 122 (the second condition) is selected, correction content of the frequency response to be corrected by this equalizer 107A is automatically set to a correction content that corresponds to a diaphragm 121 (see FIGS. 4 through 6) mounted on a top of the case 120.

This HDD player 100B further has an equalizer 107H, a D/A converter 108H, and an output amplifier 109H, which are provided to obtain a headphone output. These equalizer 107H, D/A converter 108H, and output amplifier 109H correspond to the equalizer 107, the D/A converter 108, and the output amplifier 109 shown in FIG. 2, respectively. In this embodiment, correction content of a frequency response to be corrected by the equalizer 107H is set to a correction content that corresponds to the headphone.

The other components of this HDD player 100B are configured in the same way as the HDD player 100 shown in FIG. 2.

In this HDD player 100B, audio data output from the decoder 106 is supplied to a magnetostrictive actuator 110 as a drive signal via the equalizer 107A, the D/A converter 108A, and the output amplifier 109A in this order. Further, in this HDD player 100B, audio data output from the decoder 106 is output to a headphone jack 117 as an audio signal for a headphone via the equalizer 107H, the D/A converter 108H, and the output amplifier 109H in this order.

Thus, in the HDD player 100B shown in FIG. 16, the actuator output condition and the headphone output condition can be used at the same time. Therefore, in a condition where an audio output is obtained from the headphone connected to the headphone jack 117, by driving the magnetostrictive actuator 110 to vibrate the diaphragm, an audio output can be obtained from this diaphragm.

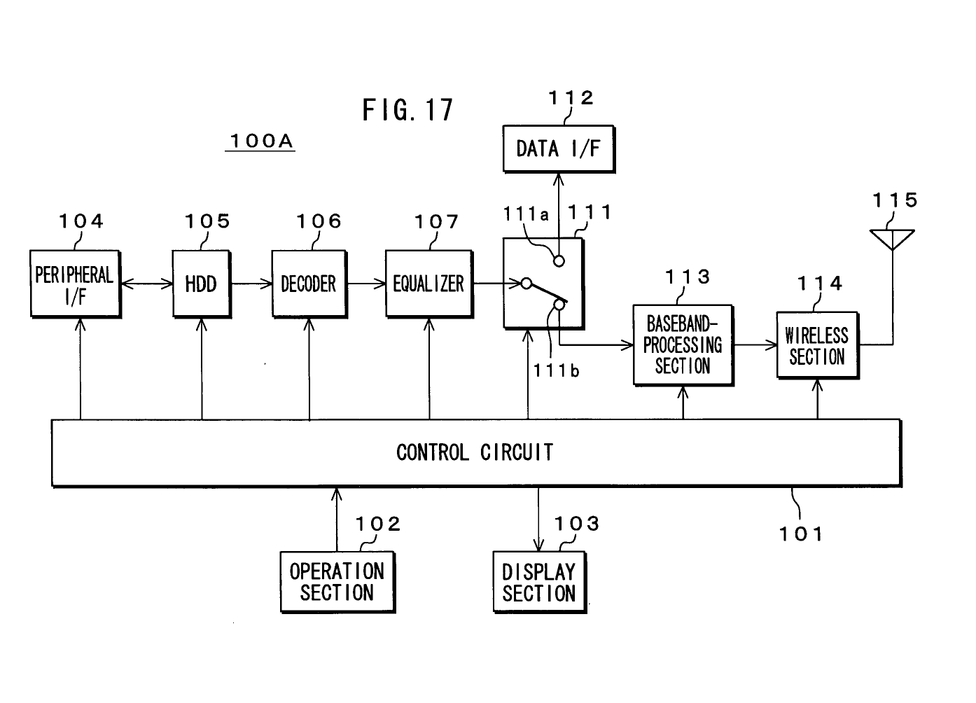

The following will describe a third embodiment of the present invention. FIG. 17 shows a configuration of a body section of an HDD player 100A as a portable audio drive unit according to the third embodiment of the invention. In this FIG. 17, components that correspond t those of FIG. 2 are indicated by the same symbols and their detailed explanation will be omitted appropriately.

This HDD player 100A has a control circuit 101 for controlling operations of the body section. To this control circuit 101, an operation section 102 and a display section 103 are connected as a user interface. The control circuit 101 also controls operations of an entirety of the player.

This HDD player 100A further has a peripheral interface 104, an HDD 105, a decoder 106, and an equalizer 107. These are the same as those of the HDD player 100 of FIG. 2.

The HDD player 100A further has a change-over switch 111, a data interface (I/F) 112, a baseband-processing section 113, a wireless section 114, and a transmission antenna 115. Among these, the baseband-processing section 113, the wireless section 114, and the transmission antenna 115 constitute a wireless transmission section.

The change-over switch 111 supplies audio data whose frequency response has been corrected by the equalizer 107 to either the data interface (I/F) 112 or the baseband-processing section 113 selectively. When connecting a later-described magnetostrictive actuator section to the body section and using it, the change-over switch 111 is connected to a fixed terminal 111a thereof under a control of the control circuit 101. The audio data output from the equalizer 107 is then supplied via the fixed terminal 111a of the change-over switch 111 to the data interface 112. On the other hand, when disconnecting the magnetostrictive actuator section from the body section and using it, the change-over switch 111 is connected to a fixed terminal 111b thereof under a control of the control circuit 101. The audio data output from the equalizer 107 is then supplied via the fixed terminal 111b of the change-over switch 111 to the baseband-processing section 113.

When connecting the later-described magnetostrictive actuator section to the body section and using it, the data interface 112 acts as a terminal section to which the data interface of this magnetostrictive actuator section is connected. The baseband-processing section 113 performs, for example, modulation processing for Bluetooth-standard communication on the audio data and converts a digital modulated signal thus obtained into analog signal, thereby obtaining a baseband signal. The wireless section 114 converts the analog signal output from the baseband-processing section 113 into a signal having a 2.5 GHz-band frequency, which is an RF communication frequency, and supplies it to the transmission antenna 115. From the transmission antenna 115, the 2.5 GHz-band frequency signal sent from the wireless section 114 is transmitted as a radio signal.

It is to be noted that the baseband-processing section 113 and the wireless section 114 become operative if the magnetostrictive actuator section is disconnected from the body section and used under the control of the control circuit 101.

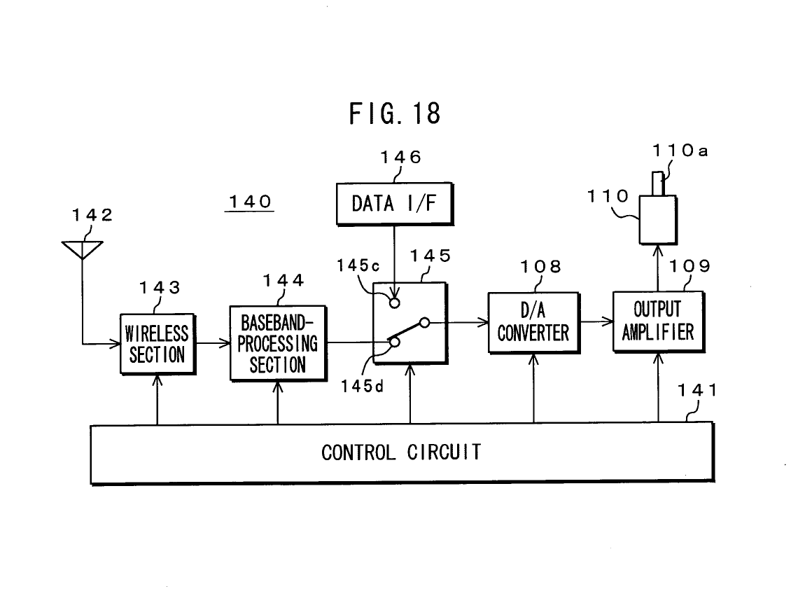

FIG. 18 shows a configuration of the magnetostrictive actuator section 140, which can be used in a condition where it is connected to the body section of the HDD player 100A shown in FIG. 17 or in a condition where it is disconnected therefrom. In this FIG. 18, components that correspond to those of FIG. 2 are indicated by the same symbols and their detailed explanation will be omitted appropriately.

This magnetostrictive actuator section 140 has a control circuit 141 for controlling operations of the entirety thereof. This magnetostrictive actuator section 140 further has a reception antenna 142, a wireless section 143, and a baseband-processing section 144. Among those, the reception antenna 142, the wireless section 143, and the baseband-processing section 144 constitute a wireless reception section.

The reception antenna 142 receives a radio signal having a 2.5 GHz-band frequency in Bluetooth-standard communication. The wireless section 143 performs any frequency conversion on a signal received through the reception antenna 142 to obtain a baseband signal. The baseband-processing section 144 converts the analog baseband signal obtained by the wireless section 143 into a digital signal and demodulates this digital signal to obtain the audio data.

Further, the magnetostrictive actuator section 140 has a change-over switch 145, a data interface (I/F) 146, a D/A converter 108, an output amplifier 109, and a magnetostrictive actuator 110.

When connecting the magnetostrictive actuator section 140 to the body section of the above-described HDD player 110A and using it, the data interface 146 acts as a terminal section connecting to the data interface 112 of this body section. The change-over switch 145 selectively supplies either audio data provided to the data interface 146 or audio data obtained by the baseband-processing section 144 to the D/A converter 108.

When connecting the magnetostrictive actuator section 140 to the body section and using it, the change-over switch 145 is connected to a fixed terminal 145c thereof under a control of the control circuit 141. The audio data supplied to the data interface 146 is then supplied to the D/A converter 108 via the fixed terminal 145c of the change-over switch 145. On the other hand, when disconnecting the magnetostrictive actuator section 140 from the body section and using it within wireless communication, the change-over switch 145 is connected to a fixed terminal 145d thereof under a control of the control circuit 141. The audio data obtained by the baseband-processing section 144 is then supplied to the D/A converter 108 via the fixed terminal 145d of the change-over switch 145;

The D/A converter 108, the output amplifier 109, and the magnetostrictive actuator 110 are the same as those in the HDD player 100 of FIG. 2.

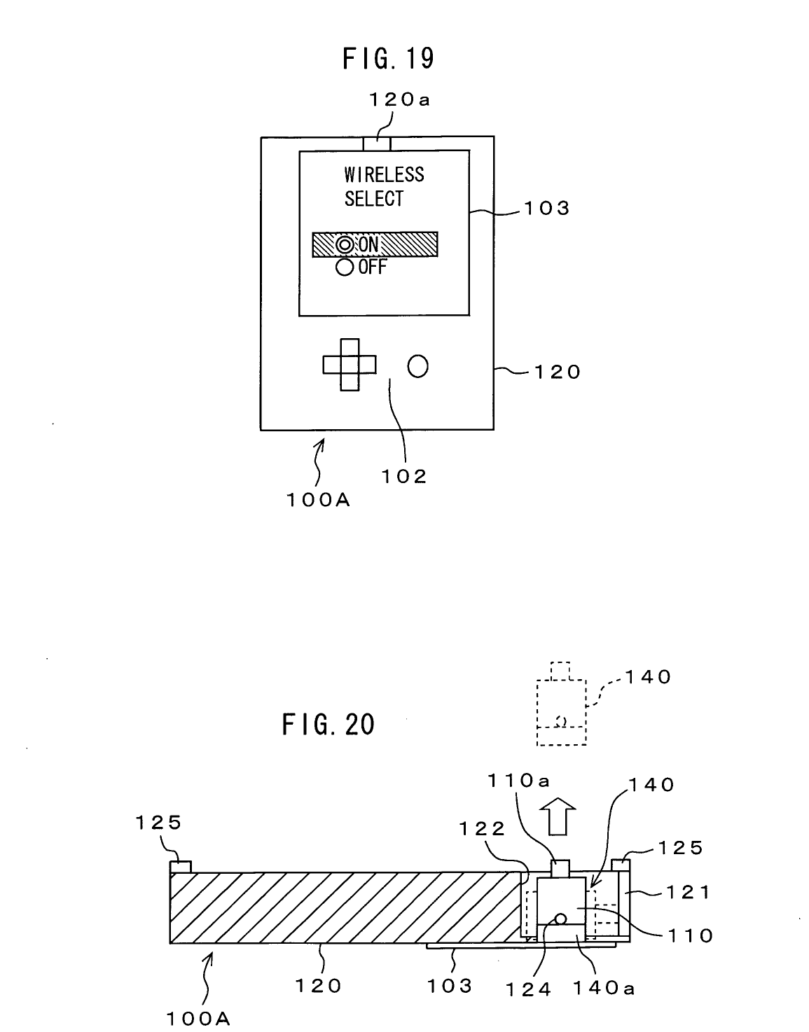

As described above, in the HDD player 100A, the magnetostrictive actuator section 140 can be used in a condition where it is connected to the body section or in a condition where it is disconnected therefrom. The user can arbitrarily select whether to use the magnetostrictive actuator section in wired condition or to use it in wireless condition. In this case, as shown in FIG. 19, the user operates the operation section 102 so that a selection screen may appear on the display section 103 arranged on a front side of a case 120 of the HDD player 100A. The user then selects “ON” (wireless use) or OFF (wired use). It is to be noted that in FIG. 19, numeral 120a indicates a position where the transmission antenna 115 (see FIG. 17) is arranged.

If the magnetostrictive actuator section 140 is used in wired condition, as shown in FIG. 20, the magnetostrictive actuator section 140 is contained in a recess portion 122 in the case 120. The magnetostrictive actuator section 140 has such a configuration that a circuit board section 140a including the wireless reception section etc. is connected to the magnetostrictive actuator 110. In such condition that the magnetostrictive actuator section 140 is contained in the recess portion 122 in the case 120, the data interface 112 (see FIG. 17) of the body section is connected to the data interface 146 (see FIG. 18) in the magnetostrictive actuator section 140, which is not shown though.

Like the magnetostrictive actuator 110 in the above-described HDD player 100, this magnetostrictive actuator section 140 can be used either in a condition where a driving rod 110a protrudes (the first condition) or in a condition where the driving rod 110a is contained (the second condition).

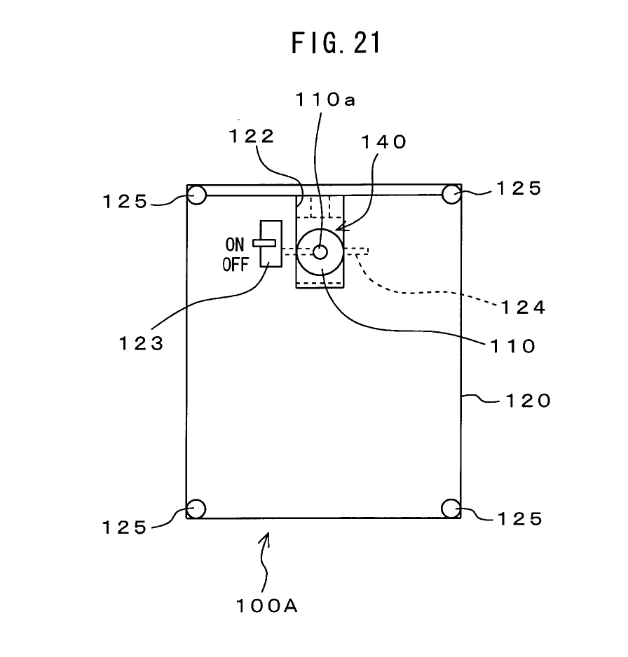

That is, if a slide operation section 123 arranged on a back side of the case 120 is set to an “ON” side, as indicated by a solid line in FIGS. 20 and 21, the magnetostrictive actuator section 140 rotates around a rotation axis 124 to permit the driving rod 110a to protrude from the case 120. On the other hand, if the slide operation section 123 is set to an “OFF” side, as indicated by a broken line in FIGS. 20 and 21, the magnetostrictive actuator 140 rotates around the rotation axis 124 to retract the driving rod 110a into the recess portion 122 so that the driving rod 110a may abut against the diaphragm 121.

It is to be noted that in FIGS. 20 and 21, components that correspond to those of FIGS. 7, 8, 11, and 12 are indicated by the same symbols and their explanation will be omitted appropriately.

If the magnetostrictive actuator section 140 is used in a wireless condition, as indicated by the broken line in FIG. 20, the magnetostrictive actuator section 140 is taken out of the recess portion 122 in the case 120. Further, in the magnetostrictive actuator section 140, the driving rod 110a of the magnetostrictive actuator 110 is used as placed on the predetermined diaphragm in a condition where this driving rod 110a abuts against this predetermined diaphragm.

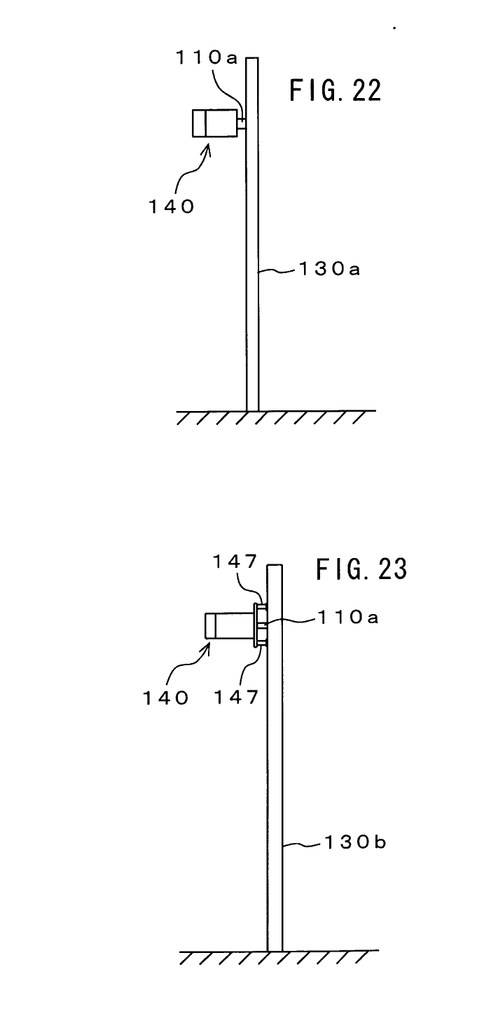

FIG. 22 shows a condition where the magnetostrictive actuator section 140 is placed on a wall 130a made of a magnetic substance, which serves as the predetermined diaphragm. In this situation, due to magnetic force of the permanent magnet 162 (see FIG. 3) that constitutes the magnetostrictive actuator 110, the magnetostrictive actuator 140 is held as placed on the magnetic wall 130a.

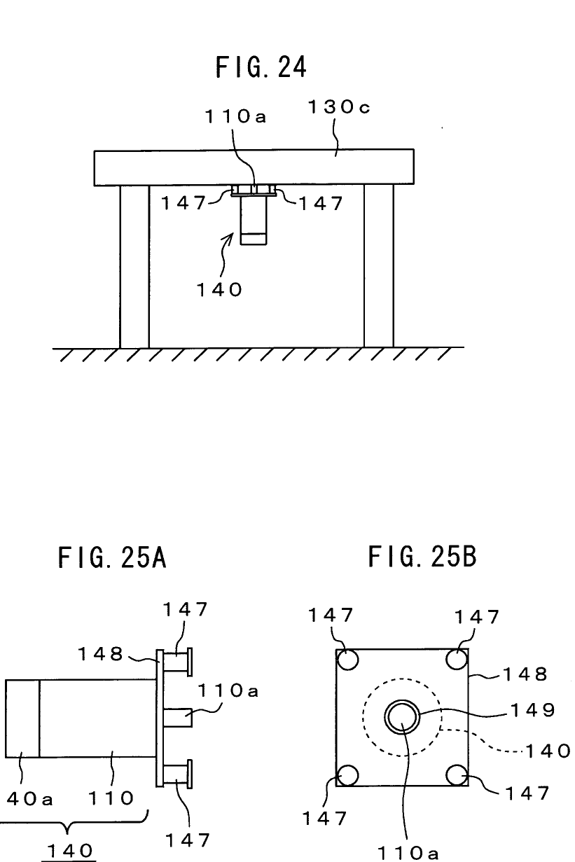

Further, FIG. 23 shows a condition where the magnetostrictive actuator section 140 is placed on a wall 130b made of a nonmagnetic substance, which serves as the predetermined diaphragm. FIG. 24 shows a condition where the magnetostrictive actuator section 140 is placed on a lower surface of an upper plate 130c (which is made of a nonmagnetic substance) of a desk that serves as the predetermined diaphragm. Thus, if the magnetostrictive actuator 140 is placed on the nonmagnetic wall 130b or the upper plate (nonmagnetic substance) 130c of the desk, the magnetostrictive actuator 140 is held as placed on the wall 130b or the upper plate 130c of the desk by, for example, suckers 147.

FIGS. 25A-25B show a configuration of the magnetostrictive actuator section 140 having the suckers 147. FIG. 25A is a side view thereof and FIG. 25B is front view thereof, namely, a view seen from a side where the driving rod 110a protrudes. In this magnetostrictive actuator section 140, on a side of the driving rod 110a of the magnetostrictive actuator 110, for example, a square-shaped sucker attachment plate 148 having a circular hole 149 through which the driving rod 110a goes at its center is fixed. The suckers 147 are attached to four corners of this sucker attachment plate 148. By thus sticking the magnetostrictive actuator section 140 to the predetermined diaphragm by using the suckers 147, the driving rod 110a of the magnetostrictive actuator section 140 can be held as abutting against the diaphragm without the user continuing to hold the magnetostrictive actuator section 140 in this abutting condition, thereby improving usability.

The following will describe reproducing operations of the body section of the HDD player 100A shown in FIG. 17 and the magnetostrictive actuator section 140 shown in FIG. 18.

First, operations will be described of “wired use” by which the magnetostrictive actuator section 140 is connected to the body section and used therein. In the body section, the change-over switch 111 is connected to the fixed terminal 111a so that the baseband-processing section 113 and the wireless section 114 may be inoperative, while in the magnetostrictive actuator section 140, the change-over switch 145 is connected to the fixed terminal 145c so that the wireless section 143 and the baseband-processing section 144 may be inoperative.

Compressed audio data is read out of the HDD 105 and supplied to the decoder 106. The decoder 106 expands the compressed audio data. The audio data output from this decoder 106 is supplied to the equalizer 107. The equalizer 107 performs any correction processing of frequency response on the audio data.

The audio data whose frequency response has been corrected by the equalizer 107 is supplied to the data interface 146 in the magnetostrictive actuator 140 via the fixed terminal 111a of the change-over switch 145 and the data interface 112.

The data interface 146 receives the audio data thus supplied and supplies it to the D/A converter 108 via the fixed terminal 145c of the change-over switch 145. The D/A converter 108 converts a digital signal of the audio data into an analog signal thereof. The analog audio signal output from the D/A converter 108 is amplified by the output amplifier 109 and then supplied to the magnetostrictive actuator 110 as a drive signal.

Accordingly, in the condition where the driving rod 110a protrudes from the case 120 (the first condition), the predetermined diaphragm against which this driving rod 110a abuts vibrates, thereby giving an audio output. On the other hand, in the condition where the driving rod 110a is retracted (the second condition), the diaphragm 121 which is mounted in the case 120 and against which this driving rod 110a abuts vibrates, thereby giving an audio output.

Next, operations will be described of “wireless use” by which the magnetostrictive actuator section 140 is disconnected from the body section and used in the disconnect condition. In the body section, the change-over switch 111 is connected to the fixed terminal 111b so that the baseband-processing section 113 and the wireless section 114 may be operative, while in the magnetostrictive actuator section 140, the change-over switch 145 is connected to the fixed terminal 145d so that the wireless section 143 and the baseband processing section 144 may be operative.

Compressed audio data is read out of the HDD 105 and supplied to the decoder 106. The decoder 106 expands the compressed audio data. The audio data output from this decoder 106 is supplied to the equalizer 107. The equalizer 107 performs any correction processing of frequency response on the audio data.

The audio data whose frequency response has been corrected by the equalizer 107 is supplied to the baseband-processing section 113 via the fixed terminal 111b of the change-over switch 111. The baseband-processing section 113 modulates the audio data and converts it into an analog signal thereof to provide a baseband signal. This baseband signal is converted in the wireless section 114 into a signal having a 2.5 GHz-band frequency, which signal is in turn transmitted from the transmission antenna 115 as a radio signal.

Then, the reception antenna 142 in the magnetostrictive actuator 140 receives the radio signal thus transmitted from the transmission antenna 115 in the body section. The signal thus received by this reception antenna 142 is supplied to the wireless section 143 where its frequency is converted to provide a baseband signal. This baseband signal is supplied to the baseband-processing section 144. The baseband-processing section 144 converts this analog baseband signal into a digital signal and demodulates it to obtain the audio data.

This audio data is supplied to the D/A converter 108 via the fixed terminal 145d of the change-over switch 145. The D/A converter 108 converts this digital signal into an analog signal. The analog audio signal output from the D/A converter 108 is amplified by the output amplifier 109 and then supplied to the magnetostrictive actuator 110 as a drive signal. Accordingly, the predetermined diaphragm against which the driving rod 110 in the magnetostrictive actuator section 140 abuts vibrates, thereby giving an audio output.

According to the above-described HDD player 100A, as in the case of the HDD player 100 shown in FIG. 2, by increasing a size of the predetermined diaphragm 130 against which the driving rod 110a abuts in a condition where this driving rod 110a protrudes from the case 120, it is possible to obtain a sufficient sound volume. This avoids a large diaphragm to be equipped in order to obtain a sufficient sound volume, thus enabling securing portability.

Further, according to this HDD player 100A, the magnetostrictive actuator section 140 can be detached from the body section. If so, audio data is radio-transmitted from the body section to the magnetostrictive actuator 140, thereby enabling the magnetostrictive actuator 110 in the magnetostrictive actuator section 140 to be driven, so that not an entirety of the HDD player 100A but only the magnetostrictive actuator section 140 may be placed on the predetermined diaphragm. This enables a merit of facilitated handling to be given.

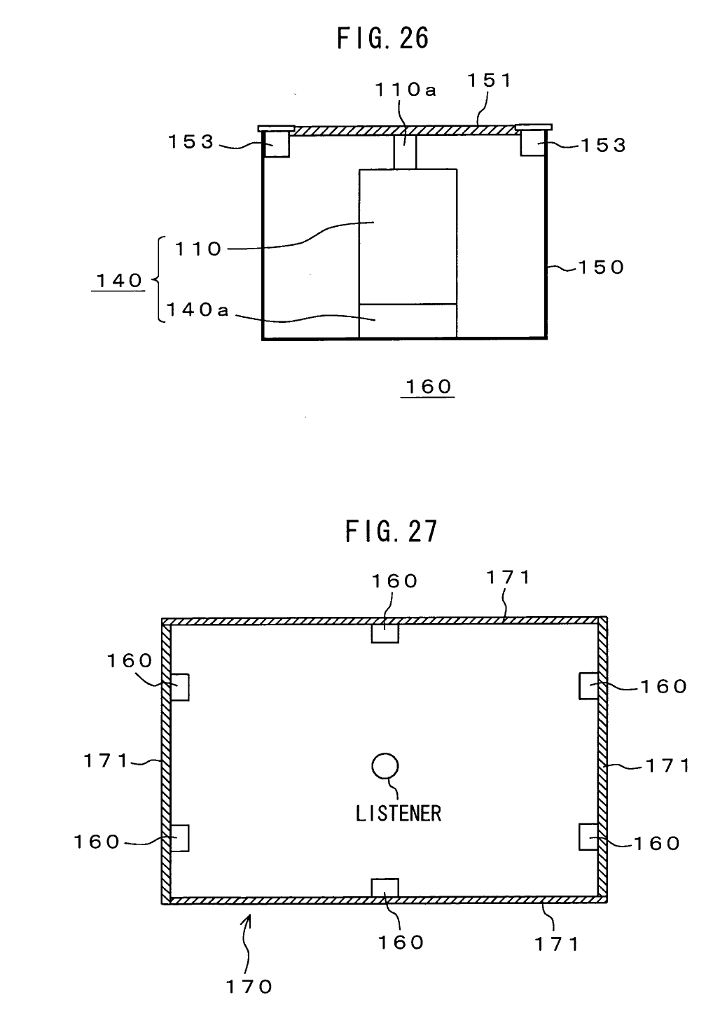

Although in the above embodiments, it has described that the driving rod 110a of the magnetostrictive actuator section 140 abuts against the predetermined diaphragm, as shown in FIG. 26, it may also be thought of that the magnetostrictive actuator section 140 is contained in a box-shaped small container 150 on a surface of which a diaphragm 151 as a displacement transfer section is placed in such a manner that the driving rod 110a of this magnetostrictive actuator section 140 may abut against the diaphragm 151. This small container 150 would be used as an audio output device 160. On the container 150, suckers 153 are provided on a side of the diaphragm 151 thereof to stick this audio output device 160 to a wall etc.

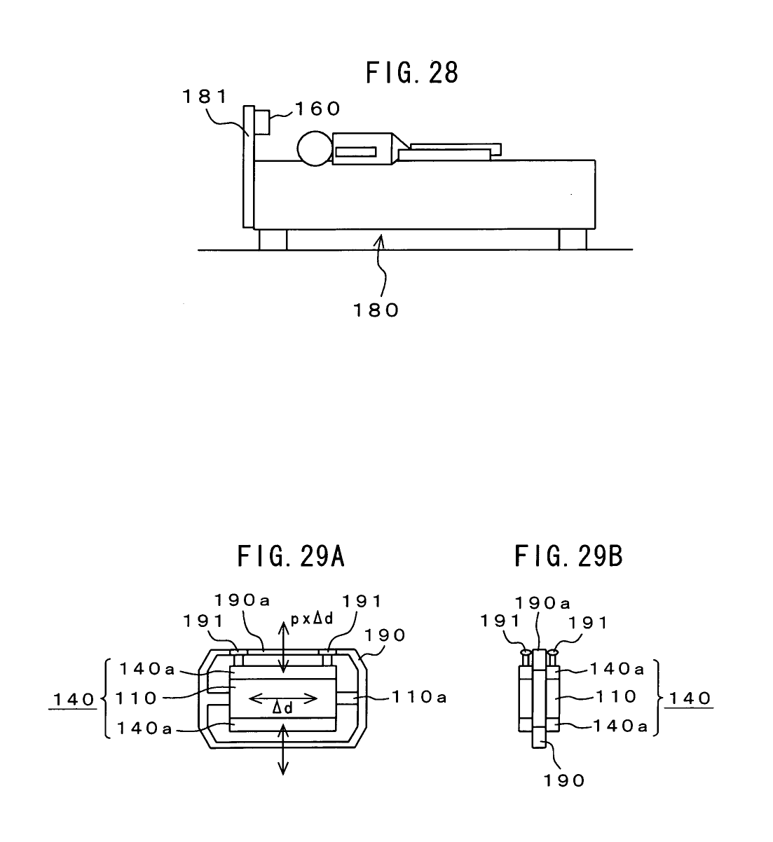

FIG. 27 shows a use example of a multi-channel speaker system that employs not only the diaphragms 151 but also walls 171, as diaphragms, of a room 170 on which the above-described audio output devices 160 are mounted. Further, FIG. 28 shows another use example that employs not only the diaphragm 151 but also a board 181, as a diaphragm, of a bed 180 on which the above-described audio output device 160 is mounted.

Although in the above embodiments, it has described that the driving rod 110a of the magnetostrictive actuator 140 abuts against the predetermined diaphragm, it may be thought of use of the magnetostrictive actuator 140 by mounting it on a displacement expander 190, which expands a displacement of this driving rod 110a, as shown in FIGS. 29A and 29B. FIG. 29A is a front view thereof and FIG. 29B is a side view thereof.

The displacement expander 190 is made of, for example, a spring material, for example, phosphor bronze. In this displacement expander 190, a displacement Ad of the driving rod 110 appears as a value multiplied by p (>1) at a section of the displacement expander 190 (displacement transfer section 190a) that is orthogonal to an axis direction of the driving rod 110a. The circuit board section 140a is provided with suckers 191, 191 for sticking to a wall etc. the magnetostrictive actuator section 140 thus attached to the displacement expander 190.

Although in the above embodiments, it has described that the displacement transfer section (the driving rod 110a itself, the diaphragm 151 mounted to the small container 150, and the displacement transfer section of the displacement expander 190) for transferring a displacement of the driving rod 110a of the magnetostrictive actuator section 140 abuts against a wall etc. that serves as the diaphragm, this displacement transfer section may abut against any part of a human being so that an audio output can be obtained through bone conduction.

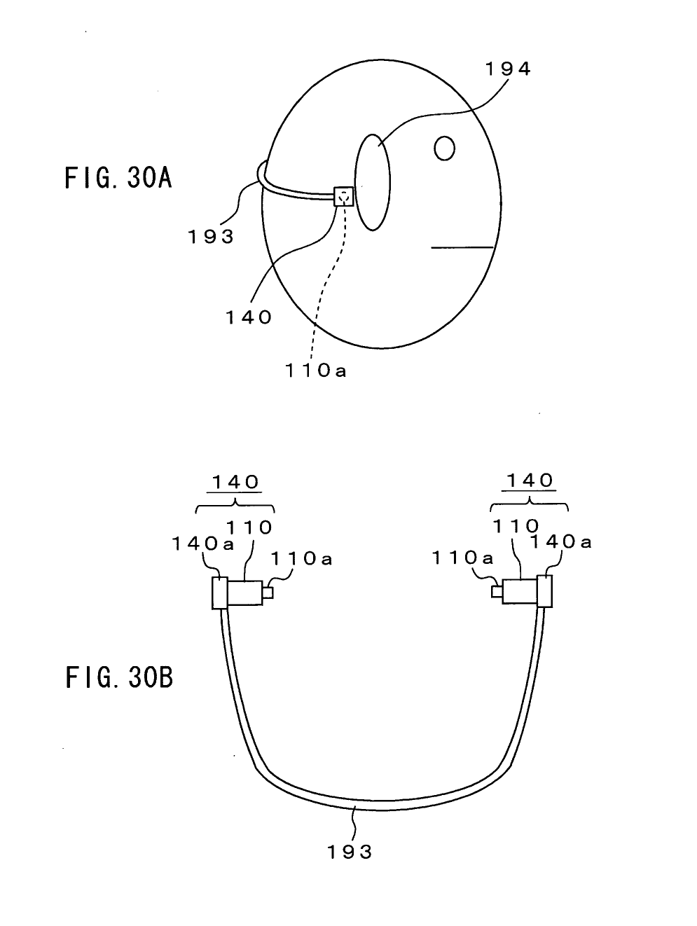

For example, the magnetostrictive actuator section 140 is attached to a neckband 193 as shown in FIG. 30B and the driving rod 110a abuts against, for example, a portion behind the ear 194 as shown in FIG. 30A. In this condition, the skull bone vibrates in accordance with a displacement of the driving rod 110a, thereby obtaining an audio output through bone conduction.

In the above embodiments, the magnetostrictive actuator 110 has not been contained in the small container 150 or attached to the displacement expander 110 but has been contained in the containing recess 122 in the case 120 in so-called exposed condition. This magnetostrictive actuator 110, however, can be contained in the recess portion 122 in the case 120 while it is contained in the small container 150 (see FIG. 26) or attached to the displacement expander 190 (see FIG. 29). It is to be noted that if the magnetostrictive actuator 110 is exposed, the displacement transfer section for transferring a displacement of the driving rod 110a relates to the driving rod 110a itself. Further, if the magnetostrictive actuator 110 is contained in the small container 150, the displacement transfer section relates to a surface constituted of the diaphragm 151. Additionally, if the magnetostrictive actuator 110 is attached to the displacement expander 190, the displacement transfer section relates to a section of the displacement expander 190 that is orthogonal to the axis direction of the driving rod 110a.

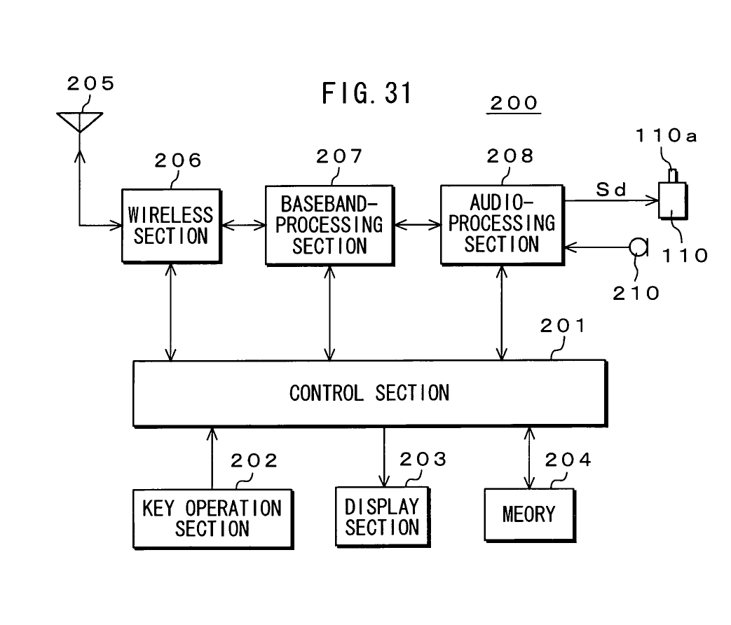

The following will describe a fourth embodiment of the present invention. FIG. 31 shows a configuration of a portable telephone 200 as a portable audio drive unit according to the fourth embodiment of the invention.

This portable telephone 200 is configured to incorporate a microcomputer and has a control section 201 for controlling operations of an entirety of the telephone. To this control section 201 are connected a key operation section 202 on which the user performs a variety of operations, a display section 203 constituted of an LCD etc. for indicating transmission/reception states, an operation state, etc., and a memory 204 used as a telephone book memory etc. in which phone numbers etc. of a lot of other parties are stored.

The portable telephone 200 further has a transmission/reception antenna 205, a wireless section 206, a baseband-processing section 207, and an audio-processing section 208. The wireless section 206 performs frequency conversion processing and demodulation/modulation processing. The baseband-processing section 207 performs separation/synthesis processing on audio information, data information etc. The audio-processing section 208 performs decoding/encoding processing on an audio signal.

To this audio-processing section 208, a magnetostrictive actuator 110 and a microphone 210 are connected. It is to be noted that this magnetostrictive actuator 110 is the same as the magnetostrictive actuator 110 that constitutes the HDD player 100 shown in FIG. 2 (see FIGS. 3A and 3B).

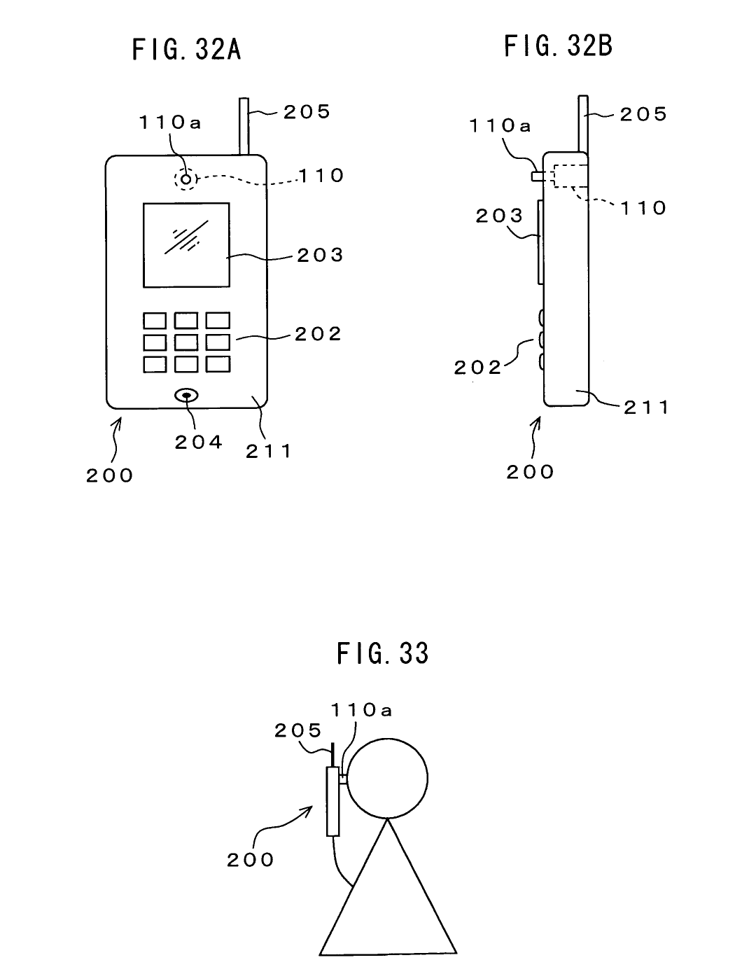

FIGS. 32A-32B show a condition where the magnetostrictive actuator 110 is mounted in the portable telephone 200. In this portable telephone 200, the magnetostrictive actuator 110 is arranged in a case 211 with the driving rod 110a protruding from the case 211.

Operations of the portable telephone 200 shown in FIG. 31 will be described in brief. First, operations at the time of reception will be explained. A portable telephone signal (high-frequency signal) received by the transmission/reception antenna 205 is supplied to the wireless section 206. The wireless section 206 converts the portable telephone signal into an intermediate-frequency signal by a mixer, from which a baseband signal is demodulated. This baseband signal is then supplied to the baseband-processing section 207.

In this baseband-processing section 207, audio information, data information (including image information and text information), etc. are separated from the baseband signal. Among these, the audio information is supplied to the audio-processing section 208 and the data information is supplied to the control section 201. The control section 201 conducts control operations based on the data information and, as occasion demands, controls the display section 203 to display an image, characters, etc. on its screen.

The audio-processing section 208 decodes the audio information to give an audio signal. A drive signal Sd that corresponds to the audio signal is supplied from this audio-processing section 208 to the magnetostrictive actuator 110. As shown in FIG. 33, the user brings the driving rod 110a of the magnetostrictive actuator 110 into contact with, for example, a site in front of or behind the ear to thus vibrate the skull bones, thereby listening to any received sound (bone-conducted sound) based on the audio signal.

It is to be noted that by permitting the driving rod 110a of the magnetostrictive actuator 110 to abut against the predetermined diaphragm, this predetermined diaphragm vibrates so that the received sound based on an audio signal can be output from this diaphragm.

Next, operations at the time of transmission thereof will be explained. An audio signal from the microphone 110 is supplied to the audio-processing section 208. The audio-processing section 208 encodes the audio signal to give audio information. This audio information is supplied to the baseband-processing section 207.

The baseband-processing section 207 synthesizes the audio information and the data information received from the control section 201 to generate a baseband signal to be transmitted. This baseband signal is supplied to the wireless section 206.

The wireless section 206 modulates the baseband signal to give an intermediate-frequency signal, which is in turn converted by the mixer into a portable telephone signal (high-frequency signal). This portable telephone signal is supplied to the transmission/reception antenna 205 to be transmitted.

According to the above-described portable telephone 200, the driving rod 110a of the magnetostrictive actuator 110 protrudes from the case 211, so that by bringing this driving rod 110a into contact with a site, for example, in front of or behind the ear, the received sound (bone-conducted sound) can be easily obtained through bone conduction. Alternatively, by permitting this driving rod 110a to abut against the predetermined diaphragm, the received sound can be easily obtained from this predetermined diaphragm.

Although the portable audio drive unit according to the embodiments of the invention have been described as ones applied to an HDD player and a portable telephone, this invention is not limited thereto.

Further, according to the above embodiments of the invention, it is possible to obtain a sufficient sound volume while securing portability.

It should be understood by those skilled in the art that various modifications, combinations, sub-combinations and alternations may occur depending on design requirements and other factors insofar as they are within the scope of the appended claims or the equivalents thereof.

What is claimed is:

1. A portable audio drive unit comprising:
a case;
an audio signal output section that outputs an audio signal; and
a magnetostrictive actuator that drives on the basis of the audio signal output from the audio output section, said magnetostrictive actuator including a displacement transfer section, said displacement transfer section having a driving rod, said displacement transfer section transferring a displacement of the driving rod,
wherein the magnetostrictive actuator is arranged in the case with the displacement transfer section protruding from the case.

2. The portable audio drive unit according to claim 1 wherein the displacement transfer section is retractable into the case.

3. The portable audio drive unit according to claim 1 wherein the magnetostrictive actuator is contained in a container whose one surface is constituted of a diaphragm with the driving rod abutting against the one surface.

4. The portable audio drive unit according to claim 2 wherein the magnetostrictive actuator is contained in a container whose one surface is constituted of a diaphragm with the driving rod abutting against the one surface.

5. The portable audio drive unit according to claim 1 wherein the magnetostrictive actuator is mounted on a displacement expander that expands a displacement of the driving rod.

6. The portable audio drive unit according to claim 2 wherein the magnetostrictive actuator is mounted on a displacement expander that expands a displacement of the driving rod.

7. The portable audio drive unit according to claim 1 wherein the case has a sucker that sticks the case to a predetermined diaphragm with the displacement transfer section abutting against this predetermined diaphragm.

8. The portable audio drive unit according to claim 2 wherein the case has a sucker that sticks the case to a predetermined diaphragm with the displacement transfer section abutting against this predetermined diaphragm.

9. The portable audio drive unit according to claim 1 further comprising:
an equalizer that corrects a frequency response of the audio signal, said equalizer being inserted between the audio signal output section and the magnetostrictive actuator; and
a correction content selection section that permits a user to select a content corrected by the equalizer among a plurality of correction contents.

10. The portable audio drive unit according to claim 2 further comprising:
an equalizer that corrects a frequency response of the audio signal, said equalizer being inserted between the audio signal output section and the magnetostrictive actuator; and
a correction content selection section that permits a user to select a content corrected by the equalizer among a plurality of correction contents.

11. The portable audio drive unit according to claim 2 further comprising:
a diaphragm attached to the case; and
a switchover mechanism that switches a condition of arranging the magnetostrictive actuator between a first condition in which the displacement transfer section protrudes from the case and a second condition in which the displacement transfer section abuts against the diaphragm.

12. The portable audio drive unit according to claim 2 wherein the magnetostrictive actuator is detachably arranged in the case, and
wherein the portable audio drive unit further comprises:
a wireless transmission section that transmits an audio signal output from the audio signal output section when the magnetostrictive actuator is detached from the case; and
a wireless reception section that receives the audio signal from the wireless transmission section when the magnetostrictive actuator is detached from the case, said wireless reception section being fixed integrally to the magnetostrictive actuator.

13. The portable audio drive unit according to claim 12 wherein the magnetostrictive actuator has a sucker that sticks the magnetostrictive actuator to a predetermined diaphragm with the displacement transfer section abutting against this predetermined diaphragm.
